(19) United States
(12) Patent Application Publication
(10) Pub. No.: US 2024/0363509 A1
(43) Pub. Date: Oct. 31, 2024

(54) MOLDED PACKAGE WITH INTERCONNECT POSTS WITH PLATED SOLDER CAPS

(71) Applicant: Skyworks Solutions, Inc., Irvine, CA (US)

(72) Inventors: Yi Liu, San Diego, CA (US); Ki Wook Lee, Irvine, CA (US); Chien Jen Wang, Taoyuan City (TW); Shaul Branchevsky, Mission Viejo, CA (US); Anthony James LoBianco, Irvine, CA (US); Reza Kasnavi, Solana Beach, CA (US)

(21) Appl. No.: 18/645,076

(22) Filed: Apr. 24, 2024

Related U.S. Application Data
(60) Provisional application No. 63/498,761, filed on Apr. 27, 2023.

(51) Int. Cl. H01L 23/498; H01L 23/31

(52) U.S. Cl. CPC H01L 23/49811; H01L 23/3121; H01L 23/49838

(57) ABSTRACT

A molded package module has a substrate, and multiple interconnect members attached to a bottom side of the substrate. A mold surrounds and extends between the interconnect members. The interconnect members can be electrically and thermally conductive and include a first post portion adjacent the substrate and a second portion adjacent the first post portion so that the first post portion is interposed between the second portion and the substrate. The second portion includes a solderable material. The molded package module can be mounted via a solderable surface at a distal end of the second portion to a motherboard.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of this disclosure relate to packaging of circuit devices, such as radio frequency modules that can be mounted on a circuit board, and more particularly to molded packages of circuit devices with interconnect posts with solder caps.

### Description of the Related Art

Circuit devices, such as radio frequency modules, can be implemented in a packaged module. Such devices can be connected to a mother board via solder balls. FIG. 1 shows an existing molded package module 10A using copper posts 2A instead of solder balls that extend from a substrate or printed circuit board (PCB) 50A to a bottom surface B of the molded package module 10A. The molded package module 10A has electronic components 6A connected to a top side 51A of the PCB 50A and covered by a top mold 8A and shield 11A. The electronic components 6A include a wafer level chip scale package (WLCSP) 20A, a flip stack 22A, a die 24A and a surface mount technology (SMT) package 26A. The copper posts 2A extend from the substrate 50A (see FIG. 2A), are overmolded with mold compound 12A (see FIG. 2B), and then the mold compound 12A is ground (see FIG. 2C) to expose the posts 2A. A solder paste 3A is then applied on the exposed post 2A and reflowed (see FIG. 2D) to form a solderable surface, or an ENEPIG (Electroless Nickel Electroless Palladium Immersion Gold) finish 4A is applied to the exposed post 2A (see FIG. 2E), or a copper organic solderability (OSP) preservative 5A is applied to the exposed post 2A (see FIG. 2F). Such a process adds to the cost and complexity of manufacturing for the circuit devices.

### SUMMARY

In some aspects, the techniques described herein relate to a molded package module including: a substrate having a top side and an opposite bottom side; a plurality of interconnect members attached to the bottom side of the substrate and being laterally spaced from each other, each of the interconnect members having a first post portion adjacent the substrate and a second portion adjacent the first post portion so that the first post portion is interposed between the second portion and the substrate, the second portion including a solderable material and a solderable surface at a distal end of the second portion via which the molded package module is configured to be mounted to a motherboard; and a mold surrounding and extending between the plurality of interconnect members.

In some aspects, the techniques described herein relate to a wireless device including: a motherboard; and a molded package module mounted on the motherboard, the molded package module including a substrate having a top side and an opposite bottom side, a plurality of interconnect members attached to the bottom side of the substrate and being laterally spaced from each other, each of the interconnect members having a first post portion adjacent the substrate and a second portion adjacent the first post portion so that the first post portion is interposed between the second portion and the substrate, the second portion including a solderable material and a solderable surface at a distal end of the second portion via which the molded package module is mounted to the motherboard, and a mold surrounding and extending between the plurality of interconnect members.

In some aspects, the techniques described herein relate to a method of manufacturing a molded package module including: forming or providing a substrate having a top side and an opposite bottom side; forming or providing a plurality of interconnect members attached to the bottom side of the substrate, each of the interconnect members having a first post portion adjacent the substrate and a second portion adjacent the first post portion so that the first post portion is interposed between the second portion and the substrate, the second portion including a solderable material; forming or providing a mold over the interconnect members; and removing at least a portion of the mold to expose the second portion of the interconnect members, the exposed second portion having a solderable surface at a distal end of the second portion, wherein the molded package module is configured to be mounted to a motherboard via the solderable surface.

### BRIEF DESCRIPTION OF THE DRAWINGS

Embodiments of this disclosure will now be described, by way of non-limiting example, with reference to the accompanying drawings.

FIG. 1 is a schematic view of an existing package module with various electronic components.

FIG. 2A is a schematic view of two interconnect posts in the package module of FIG. 1 prior to overmolding.

FIG. 2B is a schematic view of two interconnect posts in the package module of FIG. 1 following overmolding.

FIG. 2C is a schematic view of the two interconnect posts in the package module of FIG. 1 following grinding of the overmold to expose the interconnect posts.

FIG. 2D is a schematic view of the interconnect posts of FIG. 2C with a solder pad disposed on the exposed interconnect posts.

FIG. 2E is a schematic view of the interconnect posts of FIG. 2C with an ENEPIG finish applied to the exposed interconnect posts.

FIG. 2F is a schematic view of the interconnect posts of FIG. 2C with a copper OSP applied to the exposed interconnect posts.

FIG. 3 is a schematic view of a package module with various electronic components.

FIG. 3A is a schematic view of two interconnect posts in the package module of FIG. 3 prior to overmolding.

FIG. 3B is a schematic view of two interconnect posts in the package module of FIG. 3 following overmolding.

FIG. 3C is a schematic view of the two interconnect posts in the package module of FIG. 3 following grinding of the overmold to expose the interconnect posts.

FIG. 4A is a schematic view of a step in a process of manufacturing a package.

FIG. 4B is a schematic view of a step in a process of manufacturing a package.

FIG. 4C is a schematic view of a step in a process of manufacturing a package.

FIG. 4D is a schematic partial view of a package.

FIG. 4E is a schematic partial view of a package.

FIG. 5 is a schematic view of a step in a process of mounting a package to a mother board.

FIG. 6 is a schematic view of a portion of a package.

FIG. 7 is a schematic view of a step in a process of manufacturing a package.

FIG. 8 is a schematic view of a step in a process of manufacturing a package.

FIG. 9A is a schematic view of a step in a process of manufacturing a package.

FIG. 9B is a schematic view of a step in a process of manufacturing a package.

FIG. 10A is a schematic view of a step in a process of manufacturing a package.

FIG. 10B is a schematic view of a step in a process of manufacturing a package.

FIG. 11 shows one or more of modules that are mounted on a wireless phone board that can include one or more features described herein.

FIG. 12 schematically depicts the circuit board with the shielded wafer level chip scale package installed thereon.

FIG. 13 schematically depicts a wireless device having the circuit board with the shielded wafer level chip scale package installed thereon.

FIG. 14 is a schematic diagram of one example of a communication network.

FIG. 15 is a schematic diagram of one embodiment of a mobile device.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

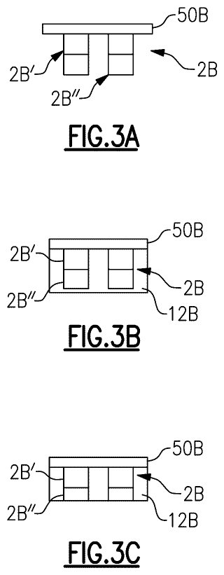

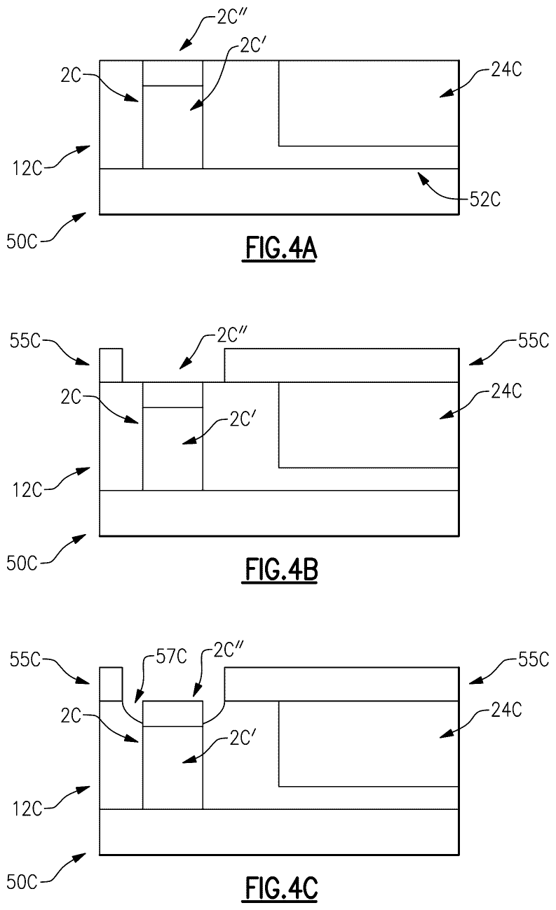

FIG. 3 shows a molded package module 10B with one or more (a plurality of) interconnect members 2B that are connected to an underside (e.g., bottom side 52B) of a substrate or printed circuit board (PCB) 50B and surrounded by mold compound 12B. The interconnect member(s) 2B can be spaced from each other. The interconnect member(s) 2B can include or be posts. A plurality of electronic components 6B are connected to a top side of the PCB 50B, including a wafer level chip scale package (WLCSP) 20B, a flip stack 22B, a die 24B and a surface mount technology (SMT) package 26B. The molded package module 10B can have other electronic components. In some implementations, the molded package module 10B can be a dual sided molded package module. Wirebonds can connect different components 6B. A top mold 8B (e.g., overmold) can be disposed over the electronic components 6B. A shield 11B is disposed over the top mold 8B to shield all of the electronic components 6B from electromagnetic (EM) interference from components outside the shield 11B. The package 10B can be mounted on a phone board or motherboard of an electronic device. Electricity can be communicated to the electrical components 6B via the interconnect members 2B (e.g., the interconnect members 2B are electrically conductive). Additionally, heat can optionally be dissipated from the package 10B via the interconnect members 2B (e.g., the interconnect members 2B are thermally conductive).

The interconnect members 2B of the molded package module 10B can, in one example, include portions shaped like posts. The interconnect members 2B can have a first post portion 2B′adjacent the substrate or PCB 50B and a second portion 2B″ adjacent the first post portion 2B′ (e.g., so that the first post portion 2B′ is interposed between the substrate 50B and the second portion 2B″). The first post portion 2B′ and the second portion 2B″ can be made of different materials. The first post portion 2B′ can be made of metal, such as copper, gold, or other metal or metal alloy (e.g., a metal interconnect portion). In one example, the first portion 2B′ can be bonded to the PCB 50B. In another example, the first portion 2B′ can be applied (e.g., formed) on the PCB 50B via a plating process. In one example, the first post portion 2B′ can be made of a metal alloy, such as a solder material (e.g., Tin_Antimony solder alloy, Sn—Sb high temperature solder alloy, other solder alloy, gold, other metal that is not oxidized in air and is wettable). In one example, the first post portion 2B′ can be made of copper using a plating process. The second portion 2B″ is of a solder material (e.g., Tin_Antimony (Sn—Sb) solder alloy), which provides a wettable surface after it is exposed (e.g., by a grinding process). The second portion 2B″ is a cap on the first post portion 2B′ (e.g., the second portion 2B″ caps the first post portion 2B′). In one example, the second portion 2B″ can be shaped like a post. In another example, discussed below, the second portion 2B″ can be a solder ball. In one example, the interconnect members 2B can have a total height (H1+H2) of about 150 microns prior to grinding and a total height of about 95 microns post grinding, with the height Hl of the first post portion 2B′ and the height H2 of the second portion 2B″ in one example being about equal (e.g., about 75 microns each) prior to grinding and the height H2 post grinding being about 20 microns. In one example, the interconnect members 2B has a circular cross-section. In one implementation, the interconnect members 2B has a uniform cross-section along the length (H1+H2) so that the first post portion 2B′ and the second portion 2B″ have the same cross-sectional dimension or diameter. In another implementation, the interconnect members 2B taper toward the end of the second portion 2B″. For example, the interconnect members 2B taper at an angle of ±10 degrees relative to vertical (e.g., the Z direction in FIG. 3). In one example, if the diameter of the interconnect members 2B (e.g., of the first post portion 2B′) adjacent the PCB 50B is about 200 microns, the diameter at the end of the second portion 2B″ (e.g., at the bottom surface B of the molded package module 10B can be between 180 microns to 220 microns.

FIGS. 3A-3C show different steps in the manufacture of the molded package module 10B. FIG. 3A shows the interconnect members 2B extending from the substrate 50B. FIG. 3B shows the interconnect members 2B overmolded with the mold compound 12B, after which a grinding process is applied to grind down and expose the second portion 2B″ of the interconnect members 2B. Following the grinding process (see FIG. 3C), the height H1 of the first post portion 2B′ is greater than the height H2 of the second portion 2B″. In one example, the height H2 of the second portion 2B″ can be between 10 microns and 50 microns, such as about 20 microns.

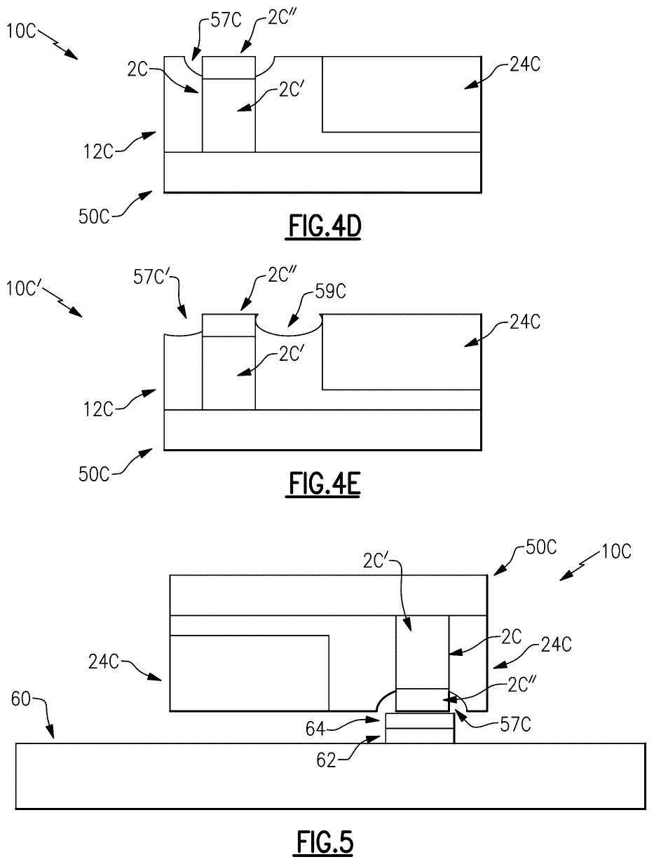

FIG. 4A-4C show steps in a process of manufacturing a package module 10C (see FIG. 4D). The package module 10C is a dual sided package module, with a die 24C on an underside of the substrate 50C. Only a portion of the package module 10C is shown, and the electronics on the top side of the substrate 50C (e.g., on an opposite side of the substrate 50C from the die 24C) are not shown, for simplicity. However, the package module 10C can have the same or similar components on the top side of the substrate 50C as described above for the package module 10B.

The package module 10C can have one or more (e.g., a plurality of) interconnect members 2C that are connected to the underside (e.g., the bottom side 52C) of the substrate 50C and surrounded by mold compound 12C. The interconnect member(s) 3C can in one example include or be shaped like posts. In the illustrated example, the interconnect members 3C have a first post portion 2C′ adjacent the substrate 50C and a second portion 2C″ adjacent the first post portion 2C′ (e.g., so that the first post portion 2C′ is interposed between the substrate 50C and the second portion 2C″). The first post portion 2C′ and the second portion 2C″ can be made of different materials. The first post portion 2C′ can be made of metal, such as copper, gold, or other metal or metal alloy (e.g., a metal interconnect portion). In one example, the first portion 2C′ can be bonded to the substrate 50C. In another example, the first portion 2C′ can be applied (e.g., formed) on the substrate 50C via a plating process. In one example, the first post portion 2C′ can be made of a metal alloy, such as a solder material (e.g., Tin_Antimony solder alloy, Sn—Sb high temperature solder alloy, other solder alloy, gold, other metal that is not oxidized in air and is wettable). In one example, the first post portion 2C′ can be made of copper using a plating process. The second portion 2C″ is of a solder material (e.g., Tin_Antimony (Sn—Sb) solder alloy), which provides a wettable surface after it is exposed (e.g., by a grinding process). The second portion 2C″ is a cap on the first post portion 2C′ (e.g., the second portion 2C″ caps the first post portion 2C′). In the illustrated example, the second portion 2C″ can be shaped like a post. In another example, discussed below, the second portion can be a solder ball. In one example, the interconnect members 2C can have a total height similar to the total height of the interconnect member 2B described above. In one example, the interconnect members 2C has a circular cross-section. In one implementation, the interconnect members 2C has a uniform cross-section along the length of the interconnect member 2C so that the first post portion 2C′ and the second portion 2C″ have the same cross-sectional dimension or diameter. In another implementation, the interconnect members 2C taper toward the end of the second portion 2C″ (e.g., in the same manner described above for the interconnect members 2B).

FIG. 4A shows the second portion 2C″ exposed (e.g., following a grinding process, such as similar to that described for FIG. 3C above) for the package module 10C. FIG. 4B shows a mask 55C applied over the distal surface of the package module 10C to cover the die 24C and a portion of the mold compound 12C, while leaving exposed the second portion 2C″ of the interconnect member(s) 2C. FIG. 4C shows a channel 57C formed around (e.g., circumferentially around) at least a portion of the second portion 2C″ of the interconnect member(s) 2C (e.g., so that the mold compound 12C extend to the edge of the package module 10C and extend to the die 24C). In one example, the channel 57C can be formed in a wet etch process. In another example, the channel 57C can be formed in a dry etch process. Following formation of the channel 57C, the mask 55C can be removed, leaving the package module 10C (see FIG. 4D). In another example, following the step shown in FIG. 4A (e.g., following a grinding process), the channel 57C can be formed using a laser ablation process (e.g., without masking) to provide the package module 10C shown in FIG. 4D. In still another example, shown in FIG. 4E, following the step shown in FIG. 4A (e.g., following a grinding process), a channel 57C′ can be formed about (e.g., about at least a portion of the circumference of, about an entire circumference of, etc.) the second portion 2C″ of the interconnect members 2C and include a channel 59C between (e.g., from) the interconnect member(s) 2C to the die 24C. The channel 57C′ and the channel 59C are formed via (dry or wet) etching without using a mask to provide the package module 10C′. In this example, mold compound 12C is removed between a side of the second portion 2C″ and the edge of the package module 10C′.

FIG. 5 shows the package module 10C being mounted to a mother board 60. The mother board 60 can have one or more (e.g., a plurality of) pads 62 (e.g., copper pads) on which solder paste 64 can be applied. The package module 10C can be positioned on the mother board 60 so that the second portion 2C″ of the interconnect member(s) 2C contact the solder paste 64. The second portion 2C″ of the interconnect member(s) 2C are soldered to the pads 62 via the solder paste 64 in a soldering process to mount the package module 10C to the mother board 60. Advantageously, the channel 57C about (e.g., about at least a portion of the circumference of, about an entire circumference of) the second portion 2C″ of the interconnect member(s) 2C provides a gap that allows outgassing from the soldering process to exit.

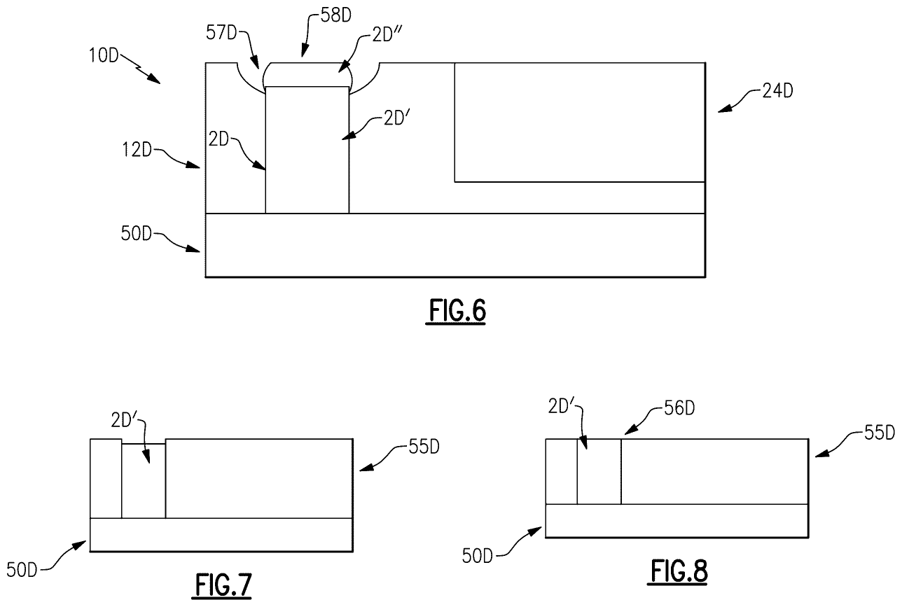

FIG. 6 shows a package module 10D. Some of the features of the package module 10D are similar to the features of package module 10C in FIG. 4D. Thus, reference numerals used to designate the various components of the package module 10D are identical to those used for identifying the corresponding components of the package module 10C in FIG. 4D, except that a “D” instead of a “C” has been added to the end of the numerical identifier. Therefore, the structure and description for the various features of the package module 10C, its advantages, and how it operates in FIG. 4D are understood to also apply to the corresponding features of the package module 10D in FIG. 6, except as described below.

The package module 10D differs from the package module 10C in that the second portion 2D″ of the interconnect member(s) 2D is a solder ball, whereas the second portion 2C″ of the interconnect member(s) 2C is a solder post or pillar. The second portion 2D″ can be ground (using a grinding process) to provide a planar distal surface 58D for the second portion 2D″ (e.g., that can interface with solder paste on pads of a mother board, such as solder paste 64 on pads 62 of the motherboard 60) to facilitate mounting of the package module 10D to a mother board.

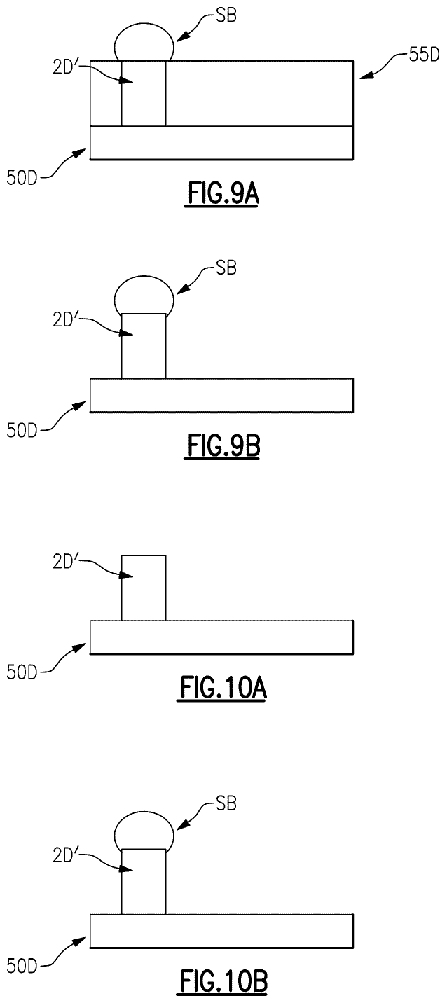

The interconnect member(s) 2D can be formed using, for example, a process shown in FIGS. 7, 8, 9A and 9B or FIGS. 7, 8, 10A and 10B, described below. FIG. 7 shows a step in the process of making the package module 10D, where a mask 55D is placed over the substrate 50D and the first post portion 2D′ of the interconnect member(s) 2D is formed (e.g., in a plating process). FIG. 8 shows a step in the process of making the package module 10D, where the mask 55D and first post portion 2D′ are ground to provide height uniformity (e.g., of all the first post portions 2D′). FIG. 9A shows a step in the process of making the package module 10D, where a solder ball SB is formed on or attached to the end of the first post portion 2D′, and FIG. 9B shows a subsequent step in the process where the mask 55D is removed from over the substrate 50D. The mold compound 12D and die 24D can then be applied to the underside of the substrate 50D (as shown in FIG. 6) and the channel 57D formed in the manner described above (e.g. using dry etching with a mask, wet etching with a mask, laser ablation without a mask).

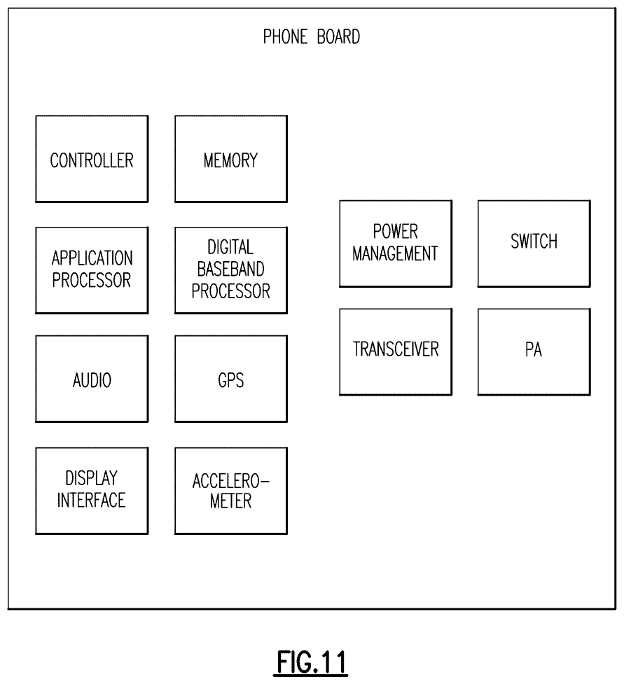

FIGS. 10A-10B show alternative steps following the step in FIG. 8. FIG. 10A shows a step in the process of making the package module 10D, where the mask 55D is removed following the grinding step to provide height uniformity, and FIG. 10B shows the step of forming or attaching a solder ball SB to the end of the first post portion 2D′. The mold compound 12D and die 24D can then be applied to the underside of the substrate 50D (as shown in FIG. 6) and the channel 57D formed in the manner described above (e.g. using dry etching with a mask, wet etching with a mask, laser ablation without a mask).

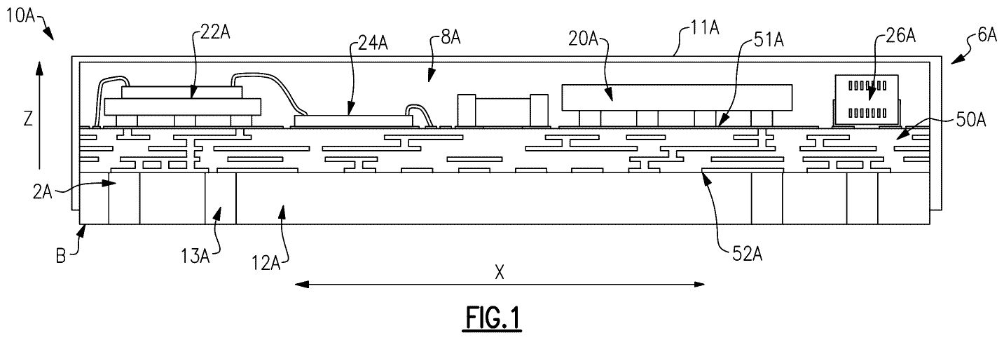

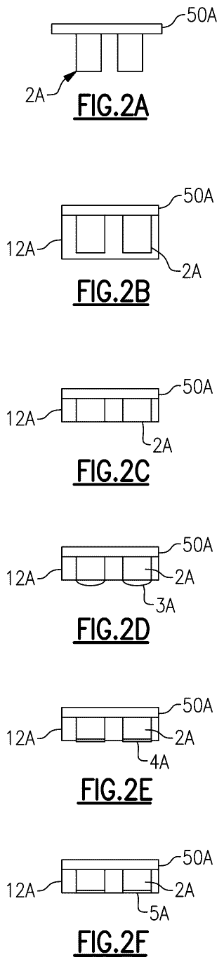

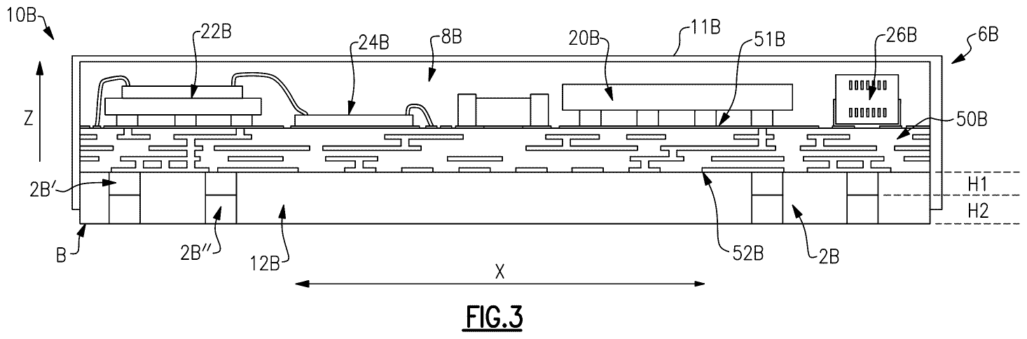

Advantageously, use of the interconnect members 2B, 2C, 2D simplifies the manufacturing process, and reduces the cost of manufacturing, of the molded package module 10B, 10C, 10C′, 10D as the steps of applying a surface finish, such as a solder on pad (see FIG. 2D), applying an ENEPIG finish (see FIG. 2E) or applying a copper OSP finish (see FIG. 2F) to create a wettable surface finish is not needed and is excluded. Further, cleaning and plating processes associated with the use of such finishes, and the equipment needed to perform these processes, can also advantageously be excluded by using the interconnect members 2B, 2C, 2D. Additionally, use of the interconnect members 2B, 2C, 2D facilitate a lower build height for the interconnect members 2B, 2C, 2D following the grinding process, and therefore a lower build height for the overall molded package module 10B, 10C, 10C′, 10D. Following the grinding step (see FIG. 3C), the exposed second portion 2B″, 2C″, 2D″ provides a solderable surface, allowing the molded package module 10B, 10C, 10C′, 10D to be mounted (e.g., to a phone board or mother board). This is in contrast to the linear post 2A in FIGS. 1-2F, where additional height (e.g., additional 30-45 micron height) is added after grinding via the addition of the solder pad 3A.

FIG. 11 shows that in some embodiments, one or more modules included in a circuit board such as a wireless phone board can include one or more of the molded package module 10B, 10C, 10C′, 10D, as described herein. Non-limiting examples of modules that can benefit from such packaging features include, but are not limited to, a controller module, an application processor module, an audio module, a display interface module, a memory module, a digital baseband processor module, a global positioning system (GPS) module, an accelerometer module, a power management module, a transceiver module, a switching module, and a power amplifier module.

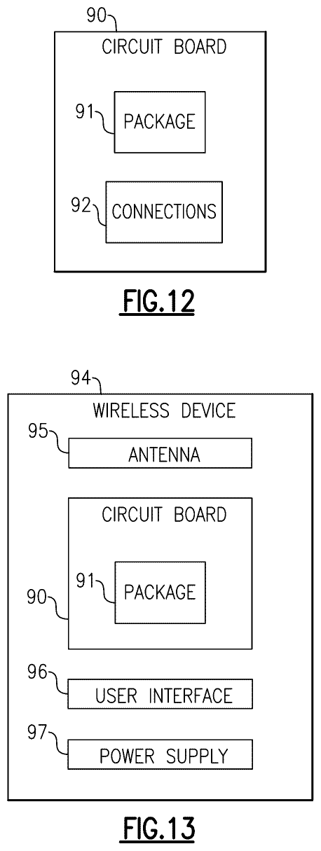

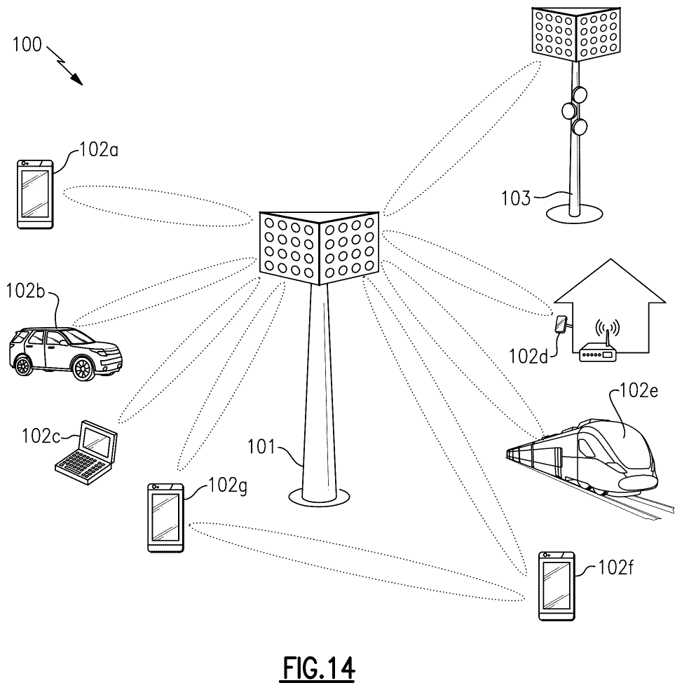

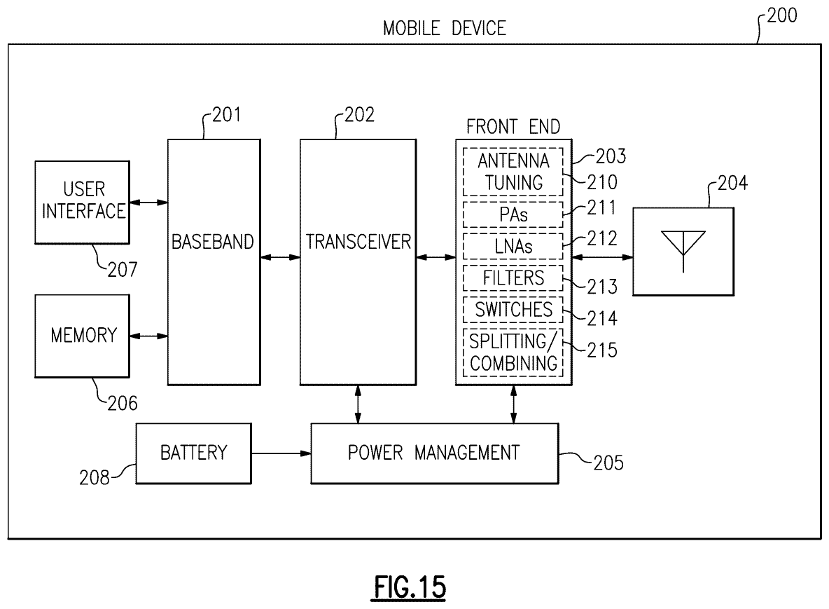

FIG. 12 schematically depicts a circuit board 90 having a package (e.g., die, SMT package, filter) 91 mounted thereon in the manner described herein (e.g., the package 91 can be a molded package module 10B, 10C, 10C′, 10D). The circuit board 90 can also include other features such as a plurality of connections 92 to facilitate operations of various packages mounted thereon. FIG. 13 schematically depicts a wireless device 94 (e.g., a cellular phone) having a circuit board 90 (e.g., a phone board). The circuit board 90 is shown to include a package (e.g., die, SMT package, filter) 91 mounted thereon in the manner described herein (e.g., the package 91 can be a molded package module 10B, 10C, 10C′, 10D). The wireless device is shown to further include other components, such as an antenna 95, a user interface 96, and a power supply 97.

FIG. 14 is a schematic diagram of one example of a communication network 100. The communication network 100 includes a macro cell base station 101, a small cell base station 103, and various examples of user equipment (UE), including a first mobile device 102a, a wireless-connected car 102b, a laptop 102c, a stationary wireless device 102d, a wireless-connected train 102e, a second mobile device 102f, and a third mobile device 102g.

Although specific examples of base stations and user equipment are illustrated in FIG. 14, a communication network can include base stations and user equipment of a wide variety of types and/or numbers.

For instance, in the example shown, the communication network 100 includes the macro cell base station 101 and the small cell base station 103. The small cell base station 103 can operate with relatively lower power, shorter range, and/or with fewer concurrent users relative to the macro cell base station 101. The small cell base station 103 can also be referred to as a femtocell, a picocell, or a microcell. Although the communication network 100 is illustrated as including two base stations, the communication network 100 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 100 of FIG. 14 supports communications using a variety of cellular technologies, including, for example, 4G LTE and 5G NR. In certain implementations, the communication network 100 is further adapted to provide a wireless local area network (WLAN), such as WiFi. Although various examples of communication technologies have been provided, the communication network 100 can be adapted to support a wide variety of communication technologies.

Various communication links of the communication network 100 have been depicted in FIG. 14. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 14, the communication links include not only communication links between UE and base stations, but also UE to UE communications and base station to base station communications. For example, the communication network 100 can be implemented to support self-fronthaul and/or self-backhaul (for instance, as between mobile device 102g and mobile device 102f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1) in the range of about 410 MHz to about 7.125 GHZ, Frequency Range 2 (FR2) in the range of about 24.250 GHz to about 52.600 GHz, or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 100 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 100 of FIG. 14 can be used to support a wide variety of advanced communication features, including, but not limited to, eMBB, uRLLC, and/or mMTC.

FIG. 15 is a schematic diagram of one embodiment of a mobile device 200. The mobile device 200 includes a baseband system 201, a transceiver 202, a front end system 203, antennas 204, a power management system 205, a memory 206, a user interface 207, and a battery 208.

The mobile device 200 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 202 generates RF signals for transmission and processes incoming RF signals received from the antennas 204. It will be understood that various functionalities associated with the transmission and receiving of RF signals can be achieved by one or more components that are collectively represented in FIG. 15 as the transceiver 202. In one example, separate components (for instance, separate circuits or dies) can be provided for handling certain types of RF signals.

The front end system 203 aids in conditioning signals transmitted to and/or received from the antennas 204. In the illustrated embodiment, the front end system 203 includes antenna tuning circuitry 210, power amplifiers (PAS) 211, low noise amplifiers (LNAs) 212, filters 213, switches 214, and signal splitting/combining circuitry 215. However, other implementations are possible.

For example, the front end system 203 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 200 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 204 can include antennas used for a wide variety of types of communications. For example, the antennas 204 can include antennas for transmitting and/or receiving signals associated with a wide variety of frequencies and communications standards.

In certain implementations, the antennas 204 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 200 can operate with beamforming in certain implementations. For example, the front end system 203 can include amplifiers having controllable gain and phase shifters having controllable phase to provide beam formation and directivity for transmission and/or reception of signals using the antennas 204. For example, in the context of signal transmission, the amplitude and phases of the transmit signals provided to the antennas 204 are controlled such that radiated signals from the antennas 204 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 204 from a particular direction. In certain implementations, the antennas 204 include one or more arrays of antenna elements to enhance beamforming.

The baseband system 201 is coupled to the user interface 207 to facilitate processing of various user input and output (I/O), such as voice and data. The baseband system 201 provides the transceiver 202 with digital representations of transmit signals, which the transceiver 202 processes to generate RF signals for transmission. The baseband system 201 also processes digital representations of received signals provided by the transceiver 202. As shown in FIG. 15, the baseband system 201 is coupled to the memory 206 of facilitate operation of the mobile device 200.

The memory 206 can be used for a wide variety of purposes, such as storing data and/or instructions to facilitate the operation of the mobile device 200 and/or to provide storage of user information.

The power management system 205 provides a number of power management functions of the mobile device 200. In certain implementations, the power management system 205 includes a PA supply control circuit that controls the supply voltages of the power amplifiers 211. For example, the power management system 205 can be configured to change the supply voltage(s) provided to one or more of the power amplifiers 211 to improve efficiency, such as power added efficiency (PAE).

As shown in FIG. 15, the power management system 205 receives a battery voltage from the battery 208. The battery 208 can be any suitable battery for use in the mobile device 200, including, for example, a lithium-ion battery.

Any of the embodiments described above can be implemented in association with mobile devices such as cellular handsets. The principles and advantages of the embodiments can be used for any systems or apparatus, such as any uplink wireless communication device, which could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kilohertz (kHz) to 300 gigahertz (GHz), such as in a frequency range from about 450 MHZ to 8.5 GHz. An acoustic wave resonator including any suitable combination of features disclosed herein be included in a filter arranged to filter a radio frequency signal in a fifth generation (5G) New Radio (NR) operating band within Frequency Range 1 (FR1). A filter arranged to filter a radio frequency signal in a 5G NR operating band can include one or more acoustic wave resonators disclosed herein. FRI can be from 410 MHz to 7.125 GHZ, for example, as specified in a current 5G NR specification. One or more acoustic wave resonators in accordance with any suitable principles and advantages disclosed herein can be included in a filter arranged to filter a radio frequency signal in a fourth generation (4G) Long Term Evolution (LTE) operating band and/or in a filter with a passband that spans a 4G LTE operating band and a 5G NR operating band.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Any of the embodiments described above can be implemented in association with mobile devices such as cellular handsets. The principles and advantages of the embodiments can be used for any systems or apparatus, such as any uplink cellular device, which could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals having a frequency in a range from about 30 kHz to 300 GHz, such as a frequency in a range from about 450 MHz to 8.5 GHZ.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A molded package module comprising:
a substrate having a top side and an opposite bottom side;
a plurality of interconnect members attached to the bottom side of the substrate and being laterally spaced from each other, each of the interconnect members having a first post portion adjacent the substrate and a second portion adjacent the first post portion so that the first post portion is interposed between the second portion and the substrate, the second portion including a solderable material and a solderable surface at a distal end of the second portion via which the molded package module is configured to be mounted to a motherboard; and
a mold surrounding and extending between the plurality of interconnect members.

2. The molded package module of claim 1 wherein the first post portion is a copper post and the second portion is a solder post.

3. The molded package module of claim 1 wherein the first post portion is made of a same material as the second portion.

4. The molded package module of claim 1 wherein a height of the first post portion is greater than a height of the second portion.

5. The molded package module of claim 4 wherein the height of the second portion is 10 to 20 microns.

6. The molded package module of claim 1 wherein the interconnect members taper so that a diameter of the first post portion adjacent the substrate is different than a diameter of the second portion proximate the solderable surface.

7. The molded package module of claim 6 wherein the interconnect members taper at an angle of ±10 degrees relative to an axis of the interconnect members.

8. The molded package module of claim 1 wherein the second portion is a solder ball.

9. The molded package module of claim 1 further comprising a channel about the second portion of the interconnect members for outgassing when the interconnect members are mounted to the motherboard.

10. The molded package module of claim 1 further comprising a die attached to the bottom side of the substrate member and between the interconnect members, the die surrounded by the mold.

11. A wireless device comprising:
a motherboard; and
a molded package module mounted on the motherboard, the molded package module including a substrate having a top side and an opposite bottom side, a plurality of interconnect members attached to the bottom side of the substrate and being laterally spaced from each other, each of the interconnect members having a first post portion adjacent the substrate and a second portion adjacent the first post portion so that the first post portion is interposed between the second portion and the substrate, the second portion including a solderable material and a solderable surface at a distal end of the second portion via which the molded package module is mounted to the motherboard, and a mold surrounding and extending between the plurality of interconnect members.

12. The wireless device of claim 11 wherein the first post portion is a copper post and the second portion is a solder post.

13. The wireless device of claim 11 wherein the first post portion is made of a same material as the second portion.

14. The wireless device of claim 11 wherein a height of the first post portion is greater than a height of the second portion.

15. The wireless device of claim 14 wherein the height of the second portion is 10 to 20 microns.

16. The wireless device of claim 11 wherein the interconnect members taper so that a diameter of the first post portion adjacent the substrate is different than a diameter of the second portion proximate the solderable surface.

17. The wireless device of claim 16 wherein the interconnect members taper at an angle of ±10 degrees relative to an axis of the interconnect members.

18. The wireless device of claim 11 wherein the interconnect members are electrically and thermally conductive.

19. The molded package module of claim 11 wherein the second portion is a solder ball.

20. The molded package module of claim 11 further comprising a channel about the second portion of the interconnect members for outgassing when the molded package module is mounted to the motherboard.
